(19) United States
(12) Patent Application Publication
(10) Pub. No.: US 2024/0258339 A1
(43) Pub. Date: Aug. 1, 2024

(54) ARRAY SUBSTRATES AND MANUFACTURING METHODS THEREOF, AND DISPLAY PANELS

(71) Applicant: Guangzhou China Star Optoelectronics Semiconductor Display Technology Co., LTd., Guangzhou (CN)

(72) Inventor: Wei WU, Guangzhou (CN)

(73) Assignee: Guangzhou China Star Optoelectronics Semiconductor Display Technology Co., LTd., Guangzhou (CN)

(21) Appl. No.: 18/511,745

(22) Filed: Nov. 16, 2023

(30) Foreign Application Priority Data
Jan. 31, 2023 (CN) 202310074456.1

(51) Int. Cl. H01L 27/12

(52) U.S. Cl. CPC H01L 27/1244; H01L 27/127

(57) ABSTRACT

An array substrate, a manufacturing method thereof, and a display panel are provided. The array substrate includes a substrate, a gate layer, a gate insulating layer, a semiconductor layer, a source and drain layer, and a protective layer stacked in sequence. The source and drain layer includes a metal laminated layer and an antioxidant protective layer. The metal laminated layer is disposed on the semiconductor layer. The antioxidant protective layer is disposed between the metal laminated layer and the protective layer.

### CROSS-REFERENCE TO RELATED APPLICATION

This application claims priority to and the benefit of Chinese Patent Application No. 202310074456.1, filed on Jan. 31, 2023, the disclosure of which is incorporated herein by reference in its entirety.

### TECHNICAL FIELD

The present disclosure relates to display technologies, and in particular to array substrates and manufacturing methods thereof, and display panels.

### BACKGROUND

As display panels develop towards large size, high resolution, high frequency, and self-emitting display modes (organic light-emitting diode (OLED), mini light-emitting diode (Mini LED), micro light-emitting diode (Micro LED)), there are increasingly high requirements for the mobility and stability of thin film transistors (TFTs) for the control switches and driving display of display panels. Currently, in the display industry, the commonly used amorphous silicon thin film transistor devices have low mobility and low on-state current (Ion), which cannot meet the requirements of high grayscale display products (reflected in insufficient charging of liquid crystal display (LCD) or insufficient brightness of OLED, Mini LED or Micro LED). The mobility of metal oxide thin film transistor devices is as high as 10 to 100 times that of amorphous silicon thin film transistor devices, which can meet the requirements of the high grayscale display products. Therefore, metal oxide thin film transistor devices and display panels including them are receiving increasing attention from the industry.

When using Silicon oxide compound as the protective layer of oxide semiconductor TFT, the interface adhesion between Silicon oxide compound and copper metal is poor, and the protective layer is prone to cracking and falling off, resulting in high production costs.

### SUMMARY

The embodiments of the present disclosure provide an array substrate, including a substrate, a gate layer, a gate insulating layer, a semiconductor layer, a source and drain layer, and a protective layer stacked in sequence. The source and drain layer includes a metal laminated layer and an antioxidant protective layer. The metal laminated layer is disposed on the semiconductor layer. The antioxidant protective layer is disposed between the metal laminated layer and the protective layer.

The embodiments of the present disclosure further provide a manufacturing method of the array substrate, including following steps.

A gate layer, a gate insulating layer, and a semiconductor layer are formed on a substrate in sequence.

A metal laminated layer is formed on the semiconductor layer.

A plasma treatment is performed on a surface of the metal laminated layer to form an antioxidant protective layer on the surface of the laminated metal layer.

The antioxidant protective layer and the laminated metal layer are patterned to form a source and drain layer.

A protective layer is formed on the source and drain layer.

The embodiments of the present disclosure further provide another manufacturing method of the array substrate, including following steps.

A gate layer, a gate insulating layer, and a semiconductor layer are formed on a substrate in sequence.

A metal laminated layer is formed on the semiconductor layer.

The metal laminated layer is patterned to form a patterned metal laminated layer.

A plasma treatment is performed on a surface of the patterned metal laminated layer to form an antioxidant protective layer on the surface of the patterned metal laminated layer. The patterned metal laminated layer and the antioxidant protective layer form a source and drain layer.

A protective layer is formed on the source and drain layer.

### BRIEF DESCRIPTION OF THE DRAWINGS

FIG. 1 is a structural schematic diagram of an array substrate provided by embodiments of the present disclosure.

FIG. 2 is a structural schematic diagram of a source and drain layer in FIG. 1.

FIG. 3 is a flowchart of the manufacturing method of the array substrate provided by embodiments of the present disclosure.

FIG. 4 is a flowchart of formation of a gate layer, a gate insulating layer, and a semiconductor layer on the substrate provided by embodiments of the present disclosure.

FIG. 5 is a flowchart of the metal laminated layer provided by embodiments of the present disclosure.

FIG. 6 is a flowchart of the manufacturing method of the array substrate provided by embodiments of the present disclosure.

The components in the accompany drawings are marked as follows.

Substrate 1; gate layer 2; gate insulating layer 3; semiconductor layer 4; source and drain layer 5; protective layer 6; metal laminated layer 51; first metal layer 511; second metal layer 512; antioxidant protective layer 52.

### DETAILED DESCRIPTION

The technical solutions in the embodiments of the present disclosure will be described clearly and completely hereafter with reference to the accompanying drawings. Apparently, the described embodiments are only a part of but not all embodiments of the present disclosure. All other embodiments obtained by persons of ordinary skill in the art based on the embodiments of the present disclosure without creative efforts shall fall within the protection scope of the present disclosure.

An array substrate, a manufacturing method thereof, and a display panel are provided by the embodiments of the present disclosure to solve the technical problem of poor interfacial adhesion between silicon oxide compound and copper metal when using silicon oxide compound as a protective layer for oxide semiconductor thin film transistors (TFTs), resulting in the protective layer that is prone to cracking and falling off, and high production costs.

As shown in FIG. 1, the embodiments of the present disclosure provide an array substrate, which may be an array substrate of back channel etched (BCE) structure. The array substrate includes a substrate 1, and a gate layer 2, a gate insulating layer 3, a semiconductor layer 4, a source and drain layer 5, and a protective layer 6 disposed on the substrate 1 in sequence.

Specifically, the gate layer 2 is disposed on the substrate 1. The gate insulating layer 3 is disposed on the gate layer 2 and the substrate 1. The semiconductor layer 4 is disposed on the gate insulating layer 3, and the semiconductor layer 4 includes a source region, a channel region, and a drain region. The source and drain layer 5 is disposed on the semiconductor layer 4. The source and drain layer 5 includes a source and a drain. The source corresponds to the source region of the semiconductor layer 4. The drain corresponds to the drain region of the semiconductor layer 4. The protective layer 6 is disposed on the gate layer 2, the gate insulating layer 3, the semiconductor layer 4, and the source and drain layer 5.

In the manufacturing process of the array substrate, copper (Cu) with low conductivity may be used as the conductive electrode to reduce the wiring resistance. In order to improve the adhesion between copper and the underlying substrate and prevent the diffusion of copper, a thin layer of other metals, such as molybdenum (Mo) titanium (Ti) alloys or alloys containing at least one of molybdenum (Mo) and titanium (Ti), may be further applied to the underlying layer of copper.

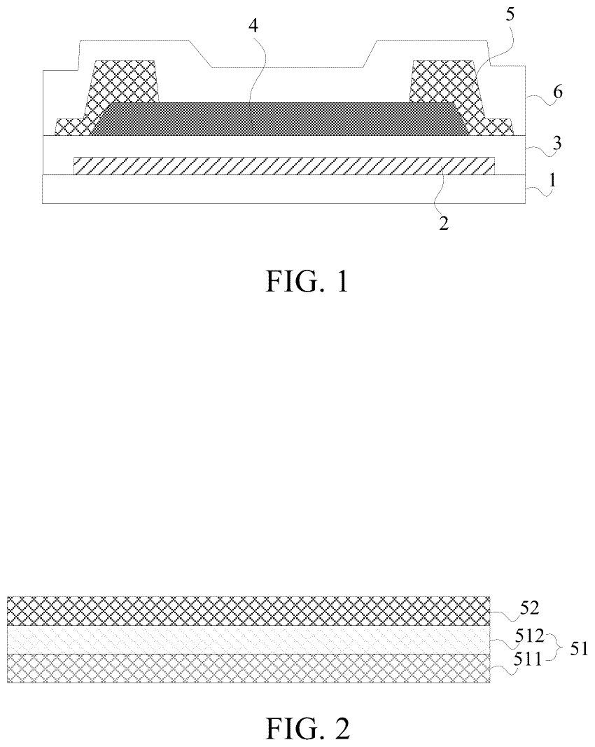

As shown in FIG. 2, in some embodiments, the source and drain layer 5 includes a metal laminated layer 51 and an antioxidant protective layer 52. The metal laminated layer 51 is disposed on the semiconductor layer 4. The antioxidant protective layer 52 is disposed between the metal laminated layer 51 and the protective layer 6.

Specifically, the metal laminated layer 51 includes a first metal layer 511 and a second metal layer 512. The first metal layer 511 is disposed on the semiconductor layer 4. The second metal layer 512 is disposed on the first metal layer 511. The antioxidant protective layer 52 is disposed on the second metal layer 512.

In some embodiments, a material of the first metal layer 511 includes molybdenum element and/or titanium element. That is, the material of the first metal layer 511 may be molybdenum alloy, titanium alloy, molybdenum-titanium alloy, molybdenum-niobium alloy, etc., without being specifically limited. A material of the second metal layer 512 is copper.

In the process of manufacturing metal oxide thin film transistor devices, due to the susceptibility of oxide semiconductor materials to hydrogen (H) plasma during the deposition of silicon nitride compounds (SiNx), they may become conductors and lose their semiconductor characteristics. Therefore, the protective layer of the metal oxide thin film transistor devices may use silicon oxides compounds (SiOx) instead of SiNx. However, the oxygen-rich environment during the deposition of SiOx may oxidize the metal copper used as the source and drain of the metal oxide thin film transistor devices, resulting in poor adhesion between SiOx and the metal copper. Under stress, SiOx thin film is prone to bulging, and even the SiOx thin film used as the protective layer may easily break and fall off, resulting in an increasing number of defective products.

To solve the problem, a layer of other materials with good adhesion to SiOx and low oxidation resistance, such as molybdenum-titanium alloy or indium tin oxide (ITO) film, may be deposited on a surface of the copper electrode in some production processes. However, these changes may require additional exposure etching processes or revised Cu etching solutions, which may significantly increase production costs.

In the array substrate provided in the embodiments of the present disclosure, the antioxidant protective layer 52 is disposed between the second metal layer 512 and the protective layer 6, which may improve the interfacial adhesion between the second metal layer 512 and the protective layer 6, and prevent the protective layer 6 from easily bulging and peeling off, thereby improving the production yield of the array substrate.

Further, a material of the antioxidant protective layer 52 includes hydrogen and nitrogen. that is, the material of the antioxidant protective layer 52 contains at least one of hydrogen (H) element and nitrogen (N) element. A material of the protective layer 6 is Silicon oxide compound (SiOx), such as SiO or SiO₂.

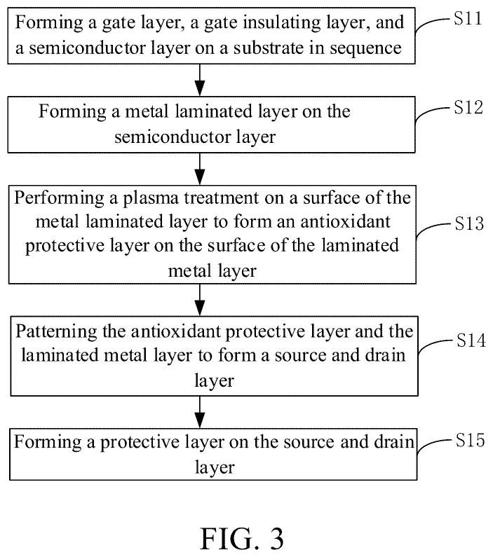

As shown in FIG. 3, the embodiments of the present disclosure further provide a manufacturing method of the array substrate, which includes step S11, step S12, step S13, step S14, and step S15.

At step S11, a gate layer 2, a gate insulating layer 3, and a semiconductor layer 4 are formed on a substrate 1 in sequence, as shown in FIG. 1.

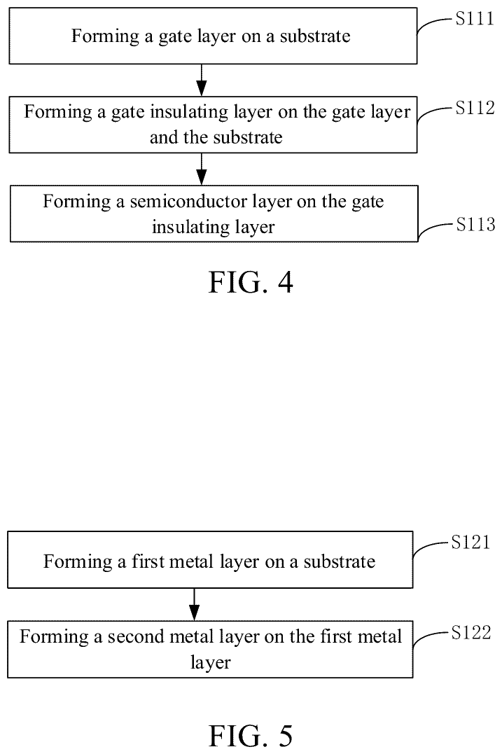

Specifically, as shown in FIG. 4, step S11 includes step S111, step S112, and step S113.

At step S111, the gate layer 2 is formed on the substrate 1;

At step S112, the gate insulating layer 3 is formed on the gate layer 2 and the substrate 1.

At step S113, the semiconductor layer 4 is formed on the gate insulating layer 3. The semiconductor layer 4 includes a source region, a channel region, and a drain region.

At step S12, a metal laminated layer 51 is formed on the semiconductor layer 4, as shown in FIG. 1.

Specifically, as shown in FIG. 5, step S12 includes step S121 and step S122.

At step S121, a first metal layer 511 is formed on the substrate 1. A metal material such as molybdenum alloy, titanium alloy, molybdenum-titanium alloy, or molybdenum-niobium alloy is deposited on the substrate 1 to form the first metal layer 511.

At step S122, a second metal layer 512 is formed on the first metal layer 511. A copper metal material is deposited on the first metal layer 511 by a physical vapor deposition (PVD) method to form the second metal layer 512.

At step S13, a plasma treatment is performed on s surface of the metal laminated layer 51 to form an antioxidant protective layer 52 on the surface of the metal laminated layer 51, as shown in FIG. 2.

Specifically, in a vacuum environment, the plasma treatment is performed on the surface of the metal laminated layer by ammonia or hydrogen for 10-120 seconds. That is, the plasma treatment is performed on the surface of the second metal layer 512 by ammonia or hydrogen, to form the antioxidant protective layer 52 on the surface of the second metal layer 512. A material of the antioxidant protective layer 52 contains at least one of hydrogen (H) and nitrogen (N).

At step S14. the antioxidant protective layer 52 and the metal laminated layer 51 are patterned to form the source and drain layer 5, as shown in FIG. 1. The source and drain layer 5 includes a source and a drain. The source corresponds to the source region of the semiconductor layer 4. The drain corresponds to the drain region of the semiconductor layer 4.

At step S15, a protective layer 6 is formed on the source and drain layers 5, as shown in FIG. 1. Silicon oxide compound (SiOx), such as SiO or SiO₂, are deposited on the source and drain layers 5 to form the protective layer 6.

In the manufacturing method of the array substrate provided by the embodiments, the plasma treatment is performed on the second metal layer 512 of the metal laminated layer 51 by ammonia or hydrogen, the copper metal of the second metal layer 512 may be combined with hydrogen, and an antioxidant protective layer 52 may be formed on the surface of the second metal layer 512. So that the copper metal is capable of not being oxidized during the subsequent deposition of Silicon oxide compound. The interfacial adhesion between copper and Silicon oxide compound may be improved. That is, the interfacial adhesion between the second metal layer and the protective layer may be improved, the production yield of the array substrate may be improved, and production costs may be reduced.

The embodiments of the present disclosure further provide a display panel, which includes the above-mentioned array substrate. The display panel also includes conventional structures such as a touch structure and an encapsulation structure. Suitable examples of the display panel include, but are not limited to, a liquid crystal display (LCD) panel, an organic light-emitting diode (OLED) panel, and a micro light-emitting diode (Micro LED) panel.

The embodiments of the present disclosure further provide an array substrate, a manufacturing method thereof, and a display panel, which include most of the technical solutions of the above embodiments, with the difference being that the manufacturing sequence of the manufacturing method of the array substrate is different.

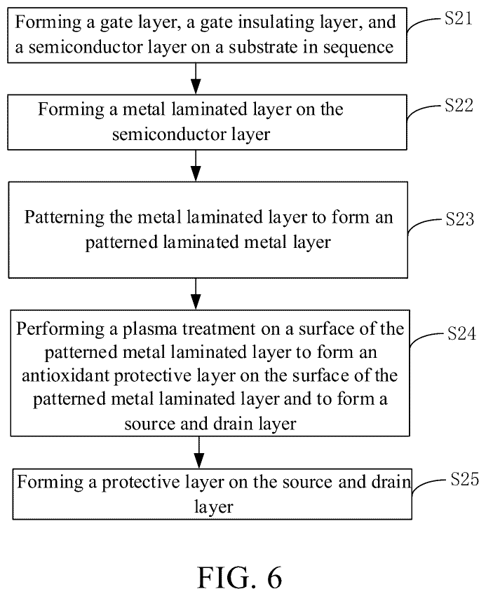

As shown in FIG. 6, some embodiments of the present disclosure further provide a manufacturing method of an array substrate, which includes the following step S21, step S22, step S23, step S24, and step S25.

At step S21, a gate layer, a gate insulating layer, and a semiconductor layer are formed on a substrate in sequence.

At step S22, a metal laminated layer is formed on the semiconductor layer.

Specifically, step S22 includes steps as follows.

A first metal layer is formed on the substrate. molybdenum alloy, titanium alloy, molybdenum-titanium alloy, molybdenum-niobium alloy or other metal materials is deposited on the substrate to form the first metal layer.

A second metal layer is formed on the first metal layer. Copper metal material is deposited on the first metal layer by a physical vapor deposition (PVD) method to form the second metal layer.

At step S23, the metal laminated layer is patterned to form a patterned metal laminated layer.

At step S24, a plasma treatment is performed on the surface of the patterned metal laminated layer to form an antioxidant protective layer on the surface of the patterned metal laminated layer, and a source and drain layer is formed.

In a vacuum environment, the surface of the patterned metal laminated layer is subjected to plasma treatment using ammonia or hydrogen for 10 to 120 seconds. That is, the surface of the second metal layer is subjected to plasma treatment using ammonia or hydrogen, resulting in the formation of an antioxidant protective layer on the surface of the second metal layer. A material of the antioxidant protective layer contains at least one of hydrogen (H) and nitrogen (N). The metal laminated layer and the antioxidant protective layer constitute a source and drain layer structure.

At step S25, a protective layer is formed on the source and drain layers. Silicon oxide compound (SiOx), such as SiO or SiO₂, is deposited on the source and drain layer to form a protective layer.

In the manufacturing method of the array substrate provided by the embodiments, the plasma treatment is performed on the second metal layer of the metal laminated layer by ammonia or hydrogen, the copper metal of the second metal layer may be combined with hydrogen, and an antioxidant protective layer may be formed on the surface of the second metal layer. So that the copper metal is capable of not being oxidized during the subsequent deposition of Silicon oxide compound. The interfacial adhesion between copper and Silicon oxide compound may be improved. That is, the interfacial adhesion between the second metal layer and the protective layer may be improved, the production yield of the array substrate may be improved, and production costs may be reduced.

In the foregoing embodiments, the description of each of the embodiments has respective focuses. For a part that is not described in detail in an embodiment, reference may be made to relevant descriptions in other embodiments.

The array substrate, the manufacturing method thereof and the display panel provided in the embodiments of the present disclosure are described in detail above. The principle and implementations of the present disclosure are described in this specification by using specific examples. The description about the foregoing embodiments is merely provided to help understand the method and core ideas of the present disclosure. Persons of ordinary skill in the art should understand that they may still make modifications to the technical solutions described in the foregoing embodiments or make equivalent replacements to some technical features thereof, without departing from the scope of the technical solutions of the embodiments of the present disclosure.

What is claimed is:

1. An array substrate, comprising:
a substrate, a gate layer, a gate insulating layer, a semiconductor layer, a source and drain layer, and a protective layer stacked in sequence;
wherein the source and drain layer comprises:
a metal laminated layer disposed on the semiconductor layer; and
an antioxidant protective layer disposed between the metal laminated layer and the protective layer.

2. The array substrate of claim 1, wherein the metal laminated layer comprises:
a first metal layer disposed on the semiconductor layer; and
a second metal layer disposed on the first metal layer.

3. The array substrate of claim 2, wherein
a material of the first metal layer comprises molybdenum element and/or titanium element; and
a material of the second metal layer is copper.

4. The array substrate of claim 1, wherein a material of the antioxidant protective layer comprises hydrogen element and/or nitrogen element.

5. The array substrate of claim 1, wherein a material of the protective layer is silicon oxide compound.

6. A manufacturing method of an array substrate, comprising following steps:
forming a gate layer, a gate insulating layer, and a semiconductor layer on a substrate in sequence;
forming a metal laminated layer on the semiconductor layer;
performing a plasma treatment on a surface of the metal laminated layer to form an antioxidant protective layer on the surface of the laminated metal layer;
patterning the antioxidant protective layer and the laminated metal layer to form a source and drain layer; and
forming a protective layer on the source and drain layer.

7. The manufacturing method of the array substrate of claim 6, wherein in a step of the performing the plasma treatment on the surface of the metal laminated layer,
in a vacuum environment, the plasma treatment is performed on the surface of the metal laminated layer by ammonia or hydrogen.

8. The manufacturing method of the array substrate of claim 7, wherein a time for the performing the plasma treatment ranges from 10 seconds to 120 seconds.

9. The manufacturing method of the array substrate of claim 7, wherein a material of the antioxidant protective layer comprises at least one of hydrogen element and nitrogen element.

10. The manufacturing method of the array substrate of claim 6, wherein a step of the forming the metal laminated layer on the semiconductor layer comprises:
forming a first metal layer on the substrate; and
forming a second metal layer on the first metal layer.

11. The manufacturing method of the array substrate of claim 10, wherein a material of the first metal layer comprises molybdenum alloy, titanium alloy, molybdenum titanium alloy, or molybdenum niobium alloy, and a material of the second metal layer is copper.

12. The manufacturing method of the array substrate of claim 6, wherein a step of the forming the gate layer, the gate insulating layer, and the semiconductor layer on the substrate in sequence comprise:
forming the gate layer on the substrate;
forming the gate insulating layer on the gate layer and the substrate; and
forming the semiconductor layer on the gate insulating layer, wherein the semiconductor layer comprises a source region, a channel region, and a drain region.

13. A manufacturing method of an array substrate, comprising following steps:
forming a gate layer, a gate insulating layer, and a semiconductor layer on a substrate in sequence;
forming a metal laminated layer on the semiconductor layer;
patterning the metal laminated layer to form a patterned metal laminated layer;
performing a plasma treatment on a surface of the patterned metal laminated layer to form an antioxidant protective layer on the surface of the patterned metal laminated layer, wherein the patterned metal laminated layer and the antioxidant protective layer form a source and drain layer; and
forming a protective layer on the source and drain layer.

14. The manufacturing method of the array substrate of claim 13, wherein in a step of the performing the plasma treatment on the surface of the patterned metal laminated layer,
in a vacuum environment, the plasma treatment is performed on the surface of the patterned metal laminated layer by ammonia or hydrogen.

15. The manufacturing method of the array substrate of claim 14, wherein a time for the performing the plasma treatment ranges from 10 seconds to 120 seconds.

16. The manufacturing method of the array substrate of claim 14, wherein a material of the antioxidant protective layer comprises at least one of hydrogen element and nitrogen element.

17. The manufacturing method of the array substrate of claim 13, wherein a step of the forming the metal laminated layer on the semiconductor layer comprises:
forming a first metal layer on the substrate; and
forming a second metal layer on the first metal layer.

18. The manufacturing method of the array substrate of claim 17, wherein a material of the first metal layer comprises molybdenum alloy, titanium alloy, molybdenum titanium alloy, or molybdenum niobium alloy, and a material of the second metal layer is copper.

19. The manufacturing method of the array substrate of claim 13, wherein a step of the forming the gate layer, the gate insulating layer, and the semiconductor layer on the substrate in sequence comprises:
forming the gate layer on the substrate;
forming the gate insulating layer on the gate layer and the substrate; and
forming the semiconductor layer on the gate insulating layer, wherein the semiconductor layer comprises a source region, a channel region, and a drain region.

20. The manufacturing method of the array substrate of claim 13, a material of the protective layer is silicon oxide compound.
